(19) United States
(12) Patent Application Publication
(10) Pub. No.: US 2013/0015055 A1
(43) Pub. Date: Jan. 17, 2013

(54) DUAL PLASMA SOURCE SYSTEMS AND METHODS FOR REACTIVE PLASMA DEPOSITION

(71) Applicant: Hariharakeshava Sarpangala Hegde, Fremont, CA (US)

(72) Inventor: Hariharakeshava Sarpangala Hegde, Fremont, CA (US)

(21) Appl. No.: 13/180,395

(22) Filed: Jul. 11, 2011

(51) Int. Cl. C23C 14/46; C23C 14/35

(52) U.S. Cl. 204/192.11; 204/298.04

(57) ABSTRACT

A plasma processing system for providing a uniform erosion of a surface of a target is provided. The system includes a dual plasma source arrangement, wherein each plasma source of the dual plasma source arrangement having a source housing for generating plasma therein. The system further includes a set of antennas, wherein at least one antenna is positioned outside of the source housing of each plasma source, at least one antenna is configured to be excited with RF power to generate the plasma inside the source housing of the each plasma source. The system yet also includes a magnet assembly configured for directing ions of the plasma within the source housing of the each plasma source through an opening of the source housing toward the surface of the target, wherein the target is positioned between a first plasma source of the dual plasma source arrangement and a second plasma source of the dual plasma source arrangement.

### BACKGROUND OF THE INVENTION

Long-throw plasma-enhanced deposition processes have long been employed for plasma processing of substrates (e.g., wafers, flat panel displays, portable device displays, etc.). In a long-throw plasma-enhanced deposition process, a plasma source is positioned some distance away from the target while bombarding the target with ions. The ions from the plasma source sputter material off the target, which causes the sputtered material to be deposited on the surface of a substrate. Typically a controlled bias voltage in the form of straight DC, or pulsed DC, or RF, is applied to the target, so that the ions in the plasma may energetically bombard the target.

To elaborate, the term “long throw” refers to the fact that the target is located typically (but not always necessarily) at least one wafer diameter away from the target in order to minimize target poisoning. For example, in the case of reactive sputter deposition, the target is a metal target but an oxide film at the substrate may be formed through injection of oxygen in the proximity of the substrate. Long-throw plasma-enhanced deposition is particularly suitable for reactive plasma deposition processes, which facilitate reactive deposition on substrates for semiconductor device manufacturing.

Embodiments of the invention relate to improving prior art long-throw plasma-enhanced deposition systems and to method steps to improve deposition processes performed via long-throw plasma-enhanced deposition systems.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, in accordance with an embodiment of the invention dual-source long throw plasma-enhanced deposition system.

FIG. 2 shows, in accordance with an embodiment of the invention, the use of steerable magnets, along with the offset of target surface with respect to the common axis of the plasma sources, to improve sputtering of the target.

FIG. 3 shows, in accordance with an embodiment of the invention, an alternative embodiment wherein the entire source may be tilted relative to the target instead of tilting the magnets themselves.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to dual remote plasma source systems and methods for long-throw plasma-enhanced deposition to achieve more full and uniform erosion of the target's surface. The ability of the dual remote plasma sources to achieve more full and uniform erosion of the target's surface in long-throw plasma-enhanced deposition applications makes the inventive process ideal for reactive deposition while minimizing target poisoning.

As the term is employed herein, target poisoning refers to the undesirable reaction of the target surface with the reactive components that are normally employed at the substrate's surface to achieve reactive deposition. Target poisoning may alter the chemical composition of the target's surface, severely change the deposition rate resulting in loss of process control, or change the composition of the material that is sputtered from the target and undesirably alter the deposition film on the wafer.

Embodiments of the invention also relate to the improvements in the target sputter rate by tilting steering magnets and offsetting of target axis with respect to the axes of the plasma sources, in a dual remote plasma source scheme. Other embodiments of the invention also relate to the arrangement of the steerable magnet coils (such as the use of multiple magnet coils) and the tilting of both sources to enable their individual axes to be directed toward the target with or without the tilting of the steering magnets.

The features and advantages of embodiments of the present invention maybe better understood with reference to the figures and discussions that follow.

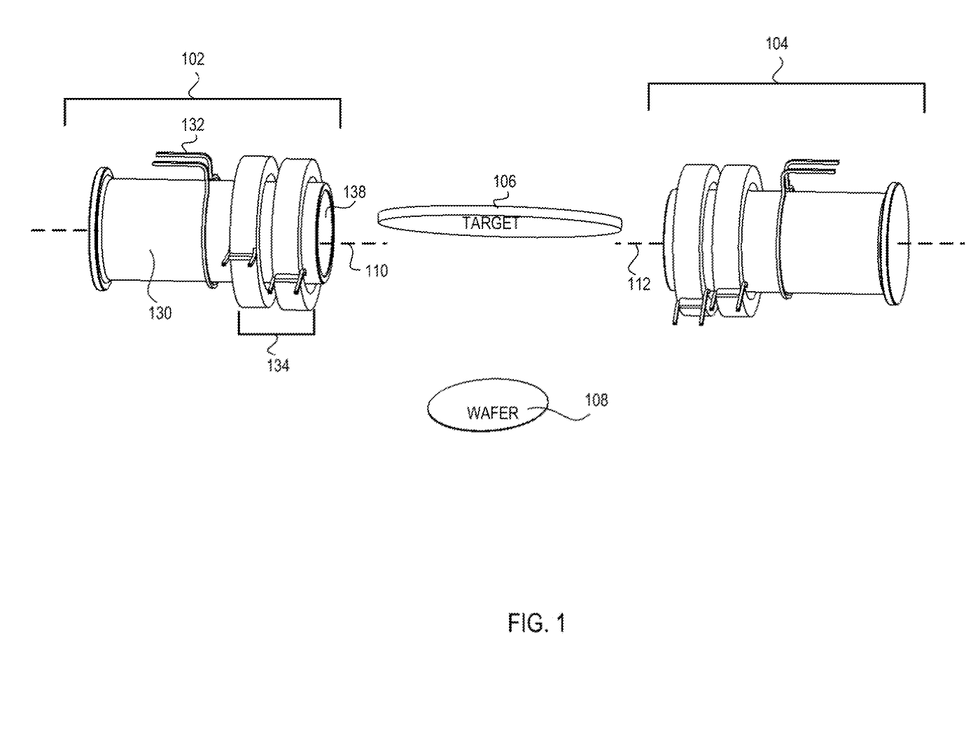

FIG. 1 shows, in accordance with an embodiment of the invention, a plasma source 102 disposed on one side of target 106 and another plasma source 104 disposed on the opposite side of target 106. Each of sources 102 and 104 includes a source housing, shown as housing 130 of source 102 for example. An antenna 132 is disposed outside of housing 130 and may be excited with RF energy to ignite a plasma inside housing 130. The ions from the plasma generated inside housing 130 are then steered by a magnet assembly 134 toward target 106 via opening 138. The plasma ions from source 102 erode one side of target 106 while the plasma ions from source 104 erode the opposite side of target 106, thereby allowing target 106 to be eroded more uniformly than if only one source were provided.

In one or more embodiments, the presence of the second plasma source provides significant advantages pertaining to the issues of uniform target erosion which prevents target poisoning in a reactive process, improved process control, improved target current and/or improved deposition uniformity/quality. As seen in FIG. 1, a second plasma source 104 having substantially the same above-described components (e.g., housing, magnet assembly, antenna, etc.). The plasma ions from the second plasma source 104 helps erode the opposite side of target 106, thereby allowing target 106 to be eroded more uniformly than if only one source were provided. Further, the provision of a second source provides additional tuning knobs to allow the process engineer to more finely tune the process by manipulating the various parameters associated with second plasma source 104.

In one or more embodiments, a liner may be disposed inside the plasma source housing. The liner may be formed of substantially the same material or the exact same material as of that the oxide of the target, that is intended to be formed at the substrate in the reactive process. Thus, if some of the liner material is sputtered by the high density plasma formed inside housing 130 (which is now with the aforementioned liner), the sputtered liner material would appear to the substrate to be substantially identical to the sputtered target material. Accordingly, substantially the same desired material would reach the surface of the wafer, eliminating contamination concerns. This liner may be made removable, such as in the form of a removable cylindrical insert for example, in order to facilitate rapid maintenance.

Generally speaking, target 106 may be positioned symmetrically with respect to source 102 and source 104 although this is not a requirement. For example, if one of sources 102 and 104 is configured to generate a denser plasma than the other, target 106 may be positioned further away from the more powerful plasma source to compensate, if desired. There may exist other reasons for unsymmetrical target positioning in a specific chamber.

A wafer 108 is disposed such that the material sputtered from target 106 is deposited on wafer 108. The target may be powered through DC, pulsed DC or RF, pulsed RF, or any combination thereof. Generally speaking, the use of the dual remote plasma sources result in more uniform removal of the target material, thereby allowing the erosion of the target to be more uniform and repeatable.

Target 106 is shown displaced from source axis 110 of source 102 and from source axis 112 of source 104. Target 106 may be offset tilted at a small distance at any angle relative to the common axis or the individual axes of the plasma sources. The distance from the target to the individual sources may be varied to optimize the target current.

Magnet assembly 134 is shown comprising two coil magnets although a single magnet may well be employed. Alternatively, more than two magnets may be employed if desired. As will be discussed later herein, magnet assembly 134 may be disposed perpendicular to source axis 110 and/or 112 (as shown in FIG. 1) or the plane of magnet assembly 134 (or of the individual coil magnet) may be disposed at an angle (other than perpendicular) relative to source axis 110 and/or 112.

In accordance with one or more embodiments of the invention, one or more of the steerable magnets may comprise multiple segments to allow the magnet to be shaped to further steer the plasma. In other words, an individual magnet does not have to be planar, and the individual constituent parts of a single magnet may be moved relative to other constituent parts of that magnet (manually or via automatic mechanical, electrical, pneumatic, or electrical actuation) to shape the magnetic field, which in turn provides another tuning knob to influence the plasma formed and/or delivered to the target.

Wafer 108 may be tilted for step coverage in one or more embodiment. Further, wafer 108 may be biased (with an RF signal, for example) to improve specific film properties in one or more deposition applications. Reactive gas may be injected around the wafer to form a reactive environment to enable reactive deposition to be formed on the substrate's surface.

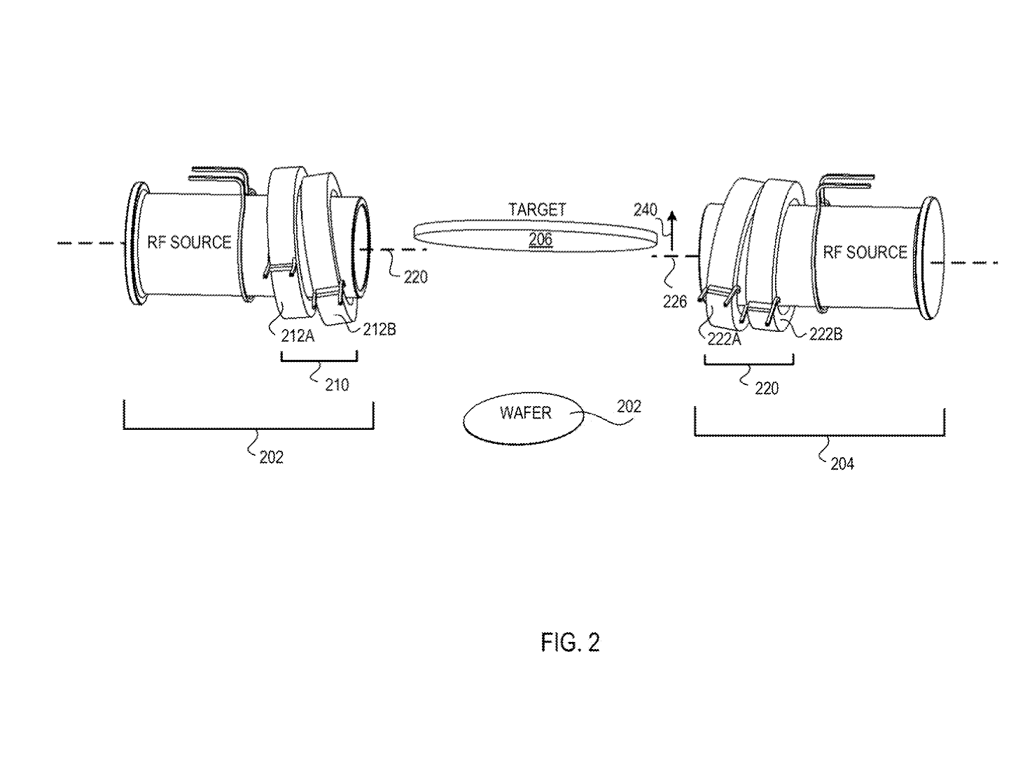

FIG. 2 shows, in accordance with an embodiment of the invention, the use of steerable magnets to improve sputtering of the target. As can be seen in FIG. 2, a plasma source 202 includes a magnet assembly 210, which in turn comprises two steerable magnets 212A and 212 B. Steerable magnet 212A and 212B may be tilted relative to source axis 220 as a single unit or each of steerable magnets 212A and 212B may be tilted at different angles other than perpendicular (as shown in FIG. 2) relative to source axis 220.

Furthermore, there are shown steerable magnets 222A and 222B associated with magnet assembly 220 of plasma source 204. Steerable magnet 222A and 222B may be tilted at the same angle relative to source axis 226 or they may tilted at different angles as shown in FIG. 2 relative to source axis 226.

Still further, each of steerable magnets 212A, 212B, 222A, and 222B may be tilted at different angles relative to one another or groups of steerable magnets associated with each plasma source may mirror the tilting of the group of steerable magnets on the other plasma source, if desired.

Relative to conventional long-throw plasma-enhanced deposition systems, target 206 is retracted further upward in the direction of arrow 240 away from the common source axis between plasma source 202 and 204. As such, target 206 is moved further away from wafer 202 to place target 206 further away from the reactive gas(es) injected in the vicinity of wafer 202 reduce at the possibility of target poisoning. Still further, the tilting of the steerable magnets in the magnet assembly allows plasma ions to be steered toward the target thereby enhancing the target current and increases the sputtering rate.

Generally speaking, deposition rate is directly proportional to the target current. Target current generally has a maximum at some specific distance from the source axis of a given plasma source, with the specific distance depending on the specific parameters of each machine or each recipe and may be determined empirically by moving the target away from the source axis and measuring, directly or indirectly, the target current. If the target is moved too far away, the target current would drop. The optimal target current may be empirically determined in this manner and advantageously taken into account in the formulation of a processing recipe.

The magnet tilt angle also has an impact on the target current such that there is a typically a maximum at some magnet tilt angle. The optimal magnet tilt angle of each magnet or magnet assembly may also be determined empirically.

In accordance with one or more embodiments of the invention, adjustments to the target current may also be made by moving the RF antenna closer to or further away from the magnets. The target current may be tuned by moving the antenna closer to the source opening (such as source opening 138 in FIG. 1) or away from that source opening. Likewise, target current may be tuned by moving the magnet assembly as a unit or individual magnets closer to the source opening or away from the source opening. Other method to optimize the target current may involve moving the sources closer or further away from the target along the source axes, for example. The discovery of these tuning steps, individually or in various combinations thereof, comprise method steps of one or more embodiments of the present invention.

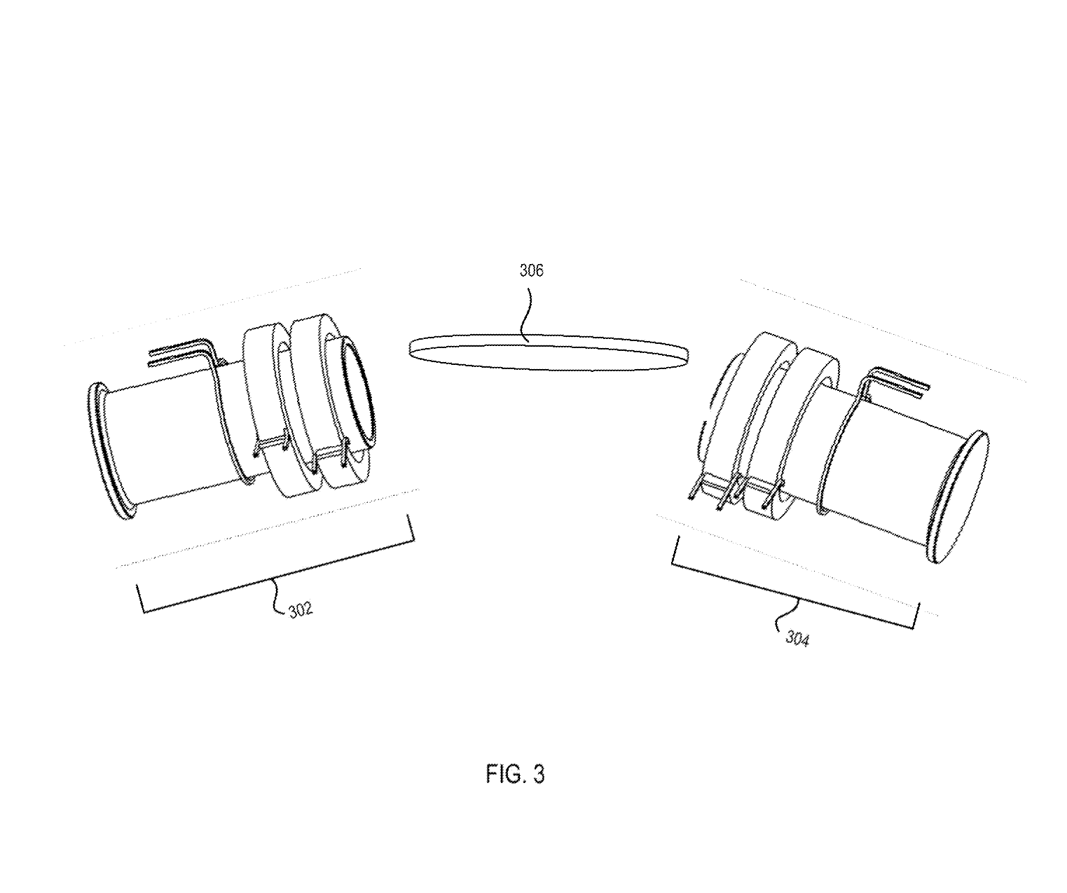

FIG. 3 shows, in accordance with an embodiment of the invention, an alternative embodiment wherein the entire source may be tilted relative to the target instead of tilting the magnets themselves. In the example of FIG. 3, both plasma source 302 and 304 are tilted toward target 306 such that the source axes of these plasma sources 302 and 304 are no longer parallel to the planar surface of target 306. By using two sources and allowing both sources to be tilted, either as a group or individually, relative to the target advantageously improves the degree by which the target may be uniformly eroded and/or to provide additional control knobs in the sputtering of the target and/or deposition of material on the surface of the substrate.

The tilting of plasma sources 302 and 304 may eliminate the need for tilting the magnets and eliminate the need to offset the target axis from the axes of the plasma sources. However, in one or more embodiments, the tilting of the two plasma sources, either together or individually, may also be performed in addition to the tilting of the magnets relative to each source axis and/or in combination with the offsetting of the target from the source axis.

As can be appreciated from the foregoing, embodiments of the invention, via various combinations of the above-discussed innovative structural improvements and/or method steps, improve the uniformity of target erosion, reduce the possibility of target poisoning, provide additional tuning knobs to the deposition process, improve the target current, and/or improve deposition rate and/or uniformity.

While this invention has been described in terms of several preferred embodiments, there are alterations, permutations, and equivalents, which fall within the scope of this invention. For example, although the figures describe the structures and arrangements of various embodiments of the improved long-throw plasma-enhanced deposition system, the invention also covers method steps as described that improve the deposition processes performed via various embodiments of the improved long-throw plasma-enhanced deposition systems. It should also be noted that there are many alternative ways of implementing the methods and apparatuses of the present invention. Although various examples are provided herein, it is intended that these examples be illustrative and not limiting with respect to the invention. If the term “set” is employed herein, such term is intended to have its commonly understood mathematical meaning to cover zero, one, or more than one member.

What is claimed is:

1. A plasma processing system for providing a uniform erosion of a surface of a target, comprising:
a dual plasma source arrangement, wherein each plasma source of said dual plasma source arrangement having a source housing for generating plasma therein;
a set of antennas, wherein at least one antenna is positioned outside of said source housing of said each plasma source, said at least one antenna is configured to be excited with RF power to generate said plasma inside said source housing of said each plasma source; and
a magnet assembly configured for directing ions of said plasma within said source housing of said each plasma source through an opening of said source housing toward said surface of said target, wherein said target is positioned between a first plasma source of said dual plasma source arrangement and a second plasma source of said dual plasma source arrangement.

2. The plasma processing system of claim 1 wherein said plasma is employed for sputter deposition.

3. The plasma processing system of claim 1 wherein a liner is disposed in said source housing of said each plasma source.

4. The plasma processing system of claim 3 wherein said liner and said target is made from similar material.

5. The plasma processing system of claim 3 wherein said liner is removable.

6. The plasma processing system of claim 1 wherein said target is positioned symmetrical with respect to said first plasma source and said second plasma source.

7. The plasma processing system of claim 1 wherein said target is positioned unsymmetrical with respect to said first plasma source and said second plasma source.

8. The plasma processing system of claim 1 wherein said target is tilted at an angle to an axis of said each plasma source.

9. The plasma processing system of claim 1 wherein said magnet assembly includes at least a single magnet.

10. The plasma processing system of claim 9 wherein said magnet assembly is disposed perpendicular to an axis of said each plasma source.

11. The plasma processing system of claim 9 wherein said magnet assembly is disposed at an angle to an axis of said each plasma source.

12. The plasma processing system of claim 9 wherein said at least said single magnet includes a plurality of segments, wherein at least a segment of said plurality of segments is moldable.

13. The plasma processing system of claim 1 wherein at least one of said dual plasma source arrangement, said set of antennas, and said magnetic assembly is movable in relation to said target, wherein moving improve sputtering on said target.

14. A method for improving sputtering on a target, comprising;
providing a dual plasma source arrangement, wherein each plasma source of said dual plasma source arrangement having a source housing for generating plasma therein;
exciting a set of antenna with power to ignite said plasma within said source housing of said each plasma source; and
steering ions of said plasma through an opening of said source housing toward said target utilizing a magnet assembly, wherein said target is positioned between a first plasma source of said dual plasma source arrangement and a second plasma source of said dual plasma source arrangement.

15. The method of claim 14 wherein said plasma is employed for sputter deposition.

16. The method of claim 15 wherein said magnet assembly includes at least one magnet configured for steering said ions, wherein said steering includes tilting said at least one magnet in relation to an axis of at least one plasma source of said dual plasma source arrangement.

17. The method of claim 16 wherein said magnet assembly is moved relative to said opening of said source housing of said each plasma source to improve said sputtering on said target.

18. The method of claim 16 wherein said set of antennas is moved relative to said opening of said source housing of said each plasma source to improve said sputtering on said target.

19. The method of claim 15 wherein said dual plasma source is moved relative to said target to improve said sputtering on said target.

20. The method of claim 15 wherein said dual plasma source is tilted in relation to said target to improve said sputtering on said target.
